(19) United States
(12) Patent Application Publication
(10) Pub. No.: US 2012/0061134 A1
(43) Pub. Date: Mar. 15, 2012

(54) SHIELDABLE BAG SYSTEM AND DEVICES

(76) Inventor: Linda Kennedy, Park City, UT (US)

(21) Appl. No.: 13/181,673

(22) Filed: Jul. 13, 2011

Related U.S. Application Data
(63) Continuation-in-part of application No. 13/166,517, filed on Jun. 22, 2011.
Application No. 13/166,517 is a continuation-in-part of application No. 12/383,348, filed on Mar. 23, 2009, now abandoned.
(60) Provisional application No. 61/072,986, filed on Apr. 4, 2008.

(51) Int. Cl. H05K 9/00

(52) U.S. Cl. 174/377; 174/350; 174/388

(57) ABSTRACT

A storage system and devices are provided for containing items and shielding the items from electromagnetic radiation, in particular, RF radiation, and holding the items in a waterproof environment. The storage system includes a first storage component which is constructed from a fabric having shieldable properties and is configured to envelope contents held therein in a shielded environment, and a second storage component which is constructed to receive the first storage component therein and provide waterproof storage for the contents. The storage system protects contents from unauthorized or surreptitious reads of stored data that may be carried on the content items by readers. The storage components of the storage system may be used independently of each other or together, as needed or desired.

### BACKGROUND OF THE INVENTION

1. Field of the Invention

The invention relates to shieldable containment devices and systems, and more particularly to reusable shieldable bags for containing items that may be carried by an individual, and more particularly, a system and devices having waterproof and RF shieldable containment enclosures.

2. Brief Description of the Related Art

There are more frequent uses of embedded storage media, such as chips, magnetic and other memory storing media in use today. For example, credit and debit cards, as well as identification cards for healthcare and insurance memberships, commonly utilize a magnetic strip that may be encoded with information. The coded stored information may be read when passed through a scanner so that the merchant or other service provider may read the information and/or import that information into a computer, such as a database or billing system. Other items, such as passports, used to identify individuals, contain digitally stored information which may be read by placing the passport in the vicinity of a scanner.

However, not only may intended decoders and readers, such as card scanner, or passport scanners read the information, but also unintended scans may be carried out even without the individual intending or knowing that that is occurring. There is a great risk that information may be retrieved from a stored source, such as the aforementioned types, or others, and used for unethical or unlawful purposes. In the era of increased security concern, it is important to protect against identity thefts and espionage activities.

A need exists for an easy and economical product that may be used to store items which a person may generally carry on them, such as credit and identification cards, and passports, and shield the stored contents from electromagnetic interference, such as, for example, electromagnetic radiation, including, for example, radio frequency and magnetic card decoders.

### SUMMARY OF THE INVENTION

A storage system and devices configured to shield RF radiation and water from items stored using the system and devices is provided. According to one embodiment, a storage device is provided for containing items and shielding the items from electromagnetic radiation, and in particular from RF radiation. Items such as, for example, passports, credit cards, membership cards and others having a storage capability such as magnetic or RFID information storage. Where an object is within a particular magnetic field (such as near a transducer head) or within a radio frequency field in the case of a RFID, the information stored may be ascertained. For example, the RFID information may transmit stored information that may be received and read by a reader. In many cases, for the transmission of the RFID information to occur, all that need be applied is a particular frequency of RF energy.

Items may be particularly vulnerable to information pirating or discovery by unauthorized readers. Though an individual may carry an item securely on one's person, that item, if encountering a radio frequency that causes a transmission of the information is still vulnerable.

Embodiments of storage devices of the present invention provide a bag which may be carried by an individual and may be configured to receive RF and/or magnetically encoded items, such as, for example, passports or credit cards, and hold these items. The bag, according to a preferred embodiment, is constructed to envelop the contents in a shielding configuration to prevent accession of the information contained on the items by shielding electromagnetic radiation, including RF radiation.

According to another embodiment, the storage system provided by the invention includes the benefits of shielding the contents as well as providing the additional benefit of a waterproof environment. According to a preferred embodiment, a multi component storage system is provided, where each component includes reclosable storage members.

The storage components, such as, for example a bag, may be reused and, according to preferred embodiments, includes a closure which may be secured to maintain the contents from falling out, and may be selectively released to allow access to the stored contents. The closure, when secured, provides an enveloping shielding environment for the contents therein.

### BRIEF DESCRIPTION OF THE DRAWING FIGURES

FIG. 1 is a from elevation view of a storage system according to my invention.

FIG. 2 is a rear elevation view of an embodiment of the first storage component of FIG. 1, shown separate from the other items, and being illustrated in a closed configuration.

FIG. 3 is a rear perspective view of the first storage component of FIG. 2 illustrated in an open configuration.

FIG. 4 is a front elevation view of an alternate embodiment of a first storage component.

FIG. 5 is a perspective view of the first storage component of FIG. 4 shown in an open condition.

FIG. 6 is a perspective view of an alternate embodiment of a first storage component looking from the top of the component into the opening, with the component being shown in a sectional view taken along the horizontal line 6-6 of FIG. 7.

FIG. 7 is a front elevation view of the first storage component alternate embodiment of FIG. 6.

FIG. 8 is a rear elevation view of an embodiment of the first storage component of FIG. 7.

FIG. 9 is a rear perspective view of the first storage component of FIG. 7 illustrated in an open configuration.

### DETAILED DESCRIPTION OF THE INVENTION

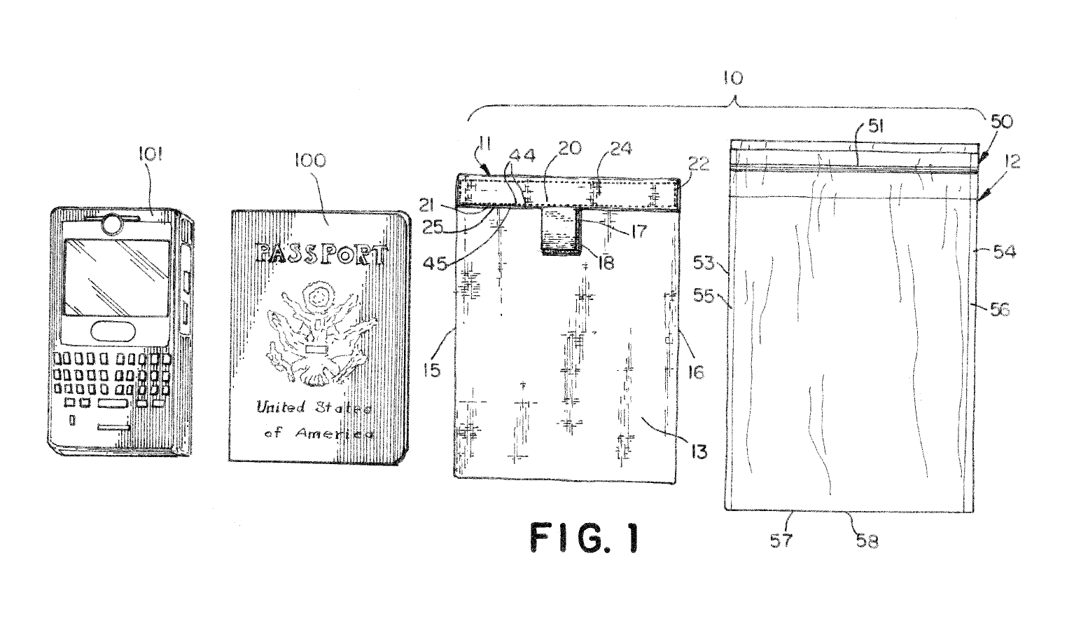

Referring to FIG. 1, a preferred embodiment of a storage system 10 is illustrated comprising a first containment member 11 and a second containment member 12. Also illustrated are examples of content items, such as the passport 100 and PDA/phone 101, which may be stored within the storage system. According to a preferred embodiment, the storage system 10 first containment member 11 may be constructed from a flexible fabric material which may be stored in a pocket of a person's clothing or outer garments, such as a jacket.

The first containment member 11 is illustrated according to a preferred embodiment having a front or first panel 13 and back or second panel 14 which are joined together or folded at their edges 15, 16. A closure 20 is provided at the top of the first panel 13 and second panel 14 and includes a first closure portion 21 and a second closure portion 22. The closure portions 21, 22 preferably may be reinforced with a layer of material such as the cover layers 24, 25 which overlay the respective surfaces of the first closure panel 21 and second closure panel 22.

The first containment member 11, which is shown configured as a flexible bag, preferably is constructed from a material that is reflective of, or shields, electromagnetic radiation, including for example, at least the RF radiation energy frequencies that are used to read information, such as information encoded on passports and the like. For example, the bag 11 may be constructed from material, such as, for example, thin metal wire conjugated yarn where a thin wire is intermingled with natural or synthetic fibers. One example is a core of a thin metal wire having a core diameter of about 0.50μ or less and a natural or synthetic fiber, and disposed around the core an additional natural or synthetic fiber. This yarn may, for example, be used to produce a fabric that may form the bag panels and closure panels. According to alternate embodiments, other examples of shieldable fabric include metallically treated fabric.

According to a preferred embodiment, the first panel 13 and second panel 14 are formed from a conductive shielding material fabric. According to one preferred embodiment, the conductive shielding material is formed from a fabric having a weight of about 4 oz/yd of nickel/copper treated polyester. The polyester, for example, according to a preferred embodiment, may be a taffeta. According to a preferred embodiment, the conductive shielding material fabric used may have a shielding effectiveness of between about 89-91 dB in the range of 100 MHz-1 GHz. A preferred embodiment of the first containment member 11 may be constructed from a polyester taffeta having a weight of about 4 oz/yd of a metal treated polyester, such as, for example, nickel/copper, and has shielding effectiveness to shield RF energy frequencies of the type used to read information on passports, identification, credit or debit cards, and other items which a person may carry.

According to one embodiment, the first containment member 11 was constructed with nickel/copper treated polyester and was durable and possessed suitable strength for retaining items within the first containment member 11.

The closure 20 is configured to include a fastening element 30, such as, for example, a hook and loop fastener arrangement as illustrated in the preferred embodiment of FIG. 1. A surface of hooks 31 is provided on one of the closure panels, such as on the second closure portion 22, and a surface of loops 32, which are matingly associated to be retained by and released from the hooks 31, is provided on a panel forming the body, such as on the outer surface of the front panel 13. The hook and loop surfaces 31, 32, respectively, may be attached to secure the closure panels portions 21, 22 over the open end portion 40 of the bag 11. The closure 20 preferably is constructed from two closure portions, such as the panel portions 21, 22 respectively. According to a preferred embodiment, a content “fill line” is illustrated as a folding axis where a folding of the closure panels 21, 22 forward or rearward direction is accomplished to close the containment member 11. The closure panel portions 21, 22 preferably are each provided to have a length to provide a substantially overlap of the folded end (as may be measured relative to the “fill line”) of the bag 11, when the bag is folded in a closed configuration.

According to some embodiments, elements for facilitating opening of the containment member 11 optionally may be provided. According to a preferred embodiment, openers 17, 18 are shown provided on the first panel 13 and second panel 14, preferably at the closure panel portions 21, 22, respectively. The openers 17, 18 facilitate separation of the closure surfaces 31, 32, respectively.

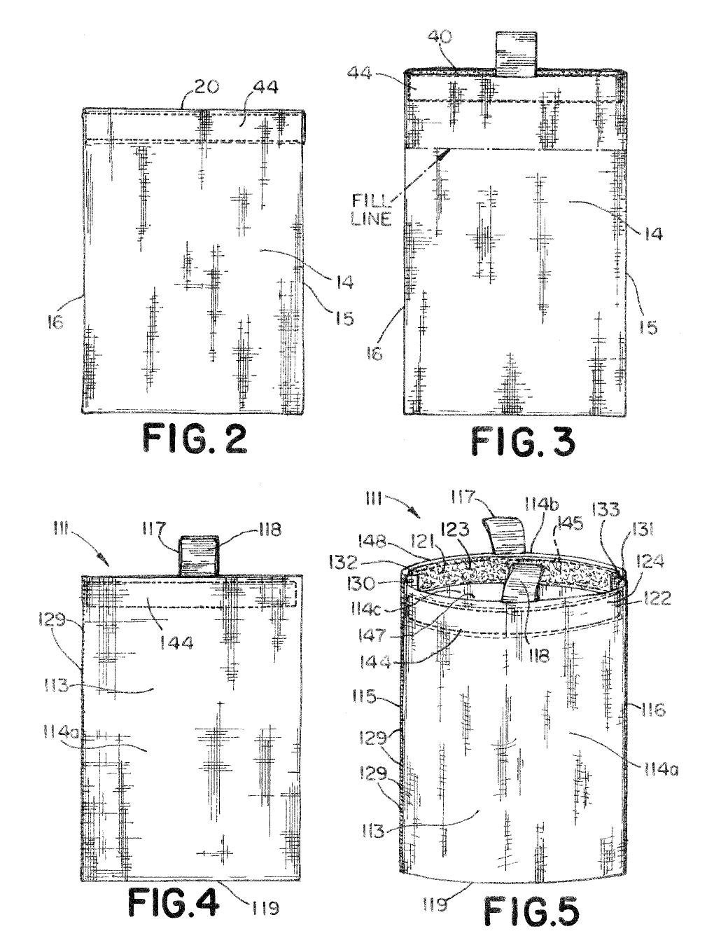

As illustrated in FIGS. 1-3, according to a preferred embodiment, the closure panel portions 21, 22 and the respective closure cover layers 24, 25 may be formed by stitching, as shown by the stitching 44, 45.

According to an embodiment of the invention, the system 10 includes a second containment member 12 which is constructed from a waterproof material, such as, for example, polyethylene or polypropylene. A watertight closure 50 is provided, such as, for example the plastic zipper 51, which may, for example, include a configuration of one or more grooves and one or more protrusions which lockingly mate with each other to form a seal. The seal formed preferably is watertight, airtight, and leak proof. The material or film from which the second containment member 12 is constructed and the watertight closure 50 together provide a waterproof environment for contents placed and sealed within the second containment member 12. According to a preferred embodiment, the second containment member 12 of the system 10 is sized to receive the first containment member 11 therein. The shielding provided by the first containment member 11 is provided when the first containment member 11 is placed in the second containment member 12. The second containment member is illustrated in FIG. 1 being formed with welds 55, 56 on each lateral edge 53, 54 thereof, and having a bottom edge 57 which preferably may be formed by a weld 58.

An alternate embodiment of a first containment member 111 is illustrated in FIGS. 4 and 5. The first containment member 111 preferably is constructed from materials described herein in connection with the first containment member 12, shown in FIGS. 1-3. The first containment member 111 is formed from a single sheet of fabric 113, which is illustrated being folded to form the bottom edge 119. The edges 115, 116 of the first containment member 111 are formed by folding the panel 113 at each lateral edge thereof to create folds 130, 131 on the front panel portion 114a. Preferably, the panel 113 also is folded at each lateral edge thereof to create folds 132, 133 on the rear panel portion 114b. The lateral edges 115, 116 are joined together, preferably, by joining the adjacent folds 130 and 132 of the first panel edge 115 and joining the adjacent folds 131, 133 at the second panel edge 116. Suitable joining means is provided. Preferably, as illustrated, the joining means is shown as a thread 129, such as nylon, cotton, or other composition, of suitable strength to hold the seam together to withstand repeated placement and removal of objects within the first containment member 111, as well as folding and storage the device 111. Closure portions 121, 122 are provided for facilitating closing and opening of the panel portions 114a, 114b. FIG. 5 illustrates the first containment member 111 in an open condition, with the closure portions 121, 122 separated from each other. According to the preferred embodiments, the closure portions preferably are constructed so that one closure portion 121 has a first surface of hooks or loops 123, and the other closure portion has a mating surface of the other of hooks or loops 124. Stitching 144, 145 may be used to facilitate attachment of the closure portions 121, 122 to a respective inner surface of the front panel portion 114a and rear panel portion 114b (the inner surface 114c of the rear panel portion 114b being illustrated in FIG. 5, the inner surface of panel portion 114a not being shown). Openers 117, 118 are provided for facilitating separation of the closure portions 121, 122. Preferably, the openers 117, 118 are provided at or proximate to the top edges 147, 148 of the respective front and rear panel portions 114a, 114b. The first containment member 111 preferably is configured to be received within the second containment member 12 (shown in FIGS. 1-3).

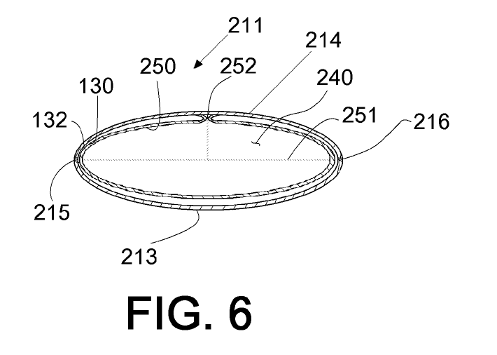

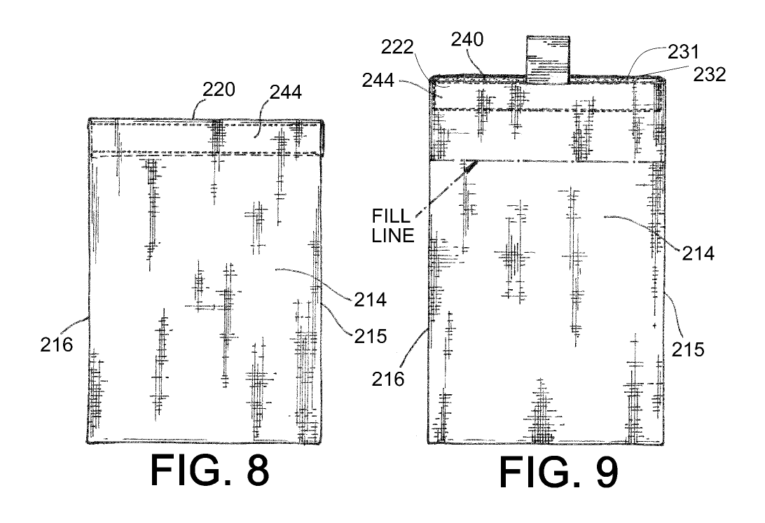

An alternate embodiment of a bag or first containment member 211 is illustrated in FIGS. 6-9. The first containment member 211 is configured as a flexible bag, and is constructed from a suitable shielding material. For example, the material preferably is a material that is reflective of, or shields, electromagnetic radiation, including for example, at least the RF radiation energy frequencies that are used to read information, such as information encoded on passports and the like. Some examples of materials that may be use to construct the first containment member 211 include those discussed herein in connection with the first containment member 11 and 111 shown and described herein. The front view of the first containment member 211 preferably may be similar to the front view of the first containment member 111.

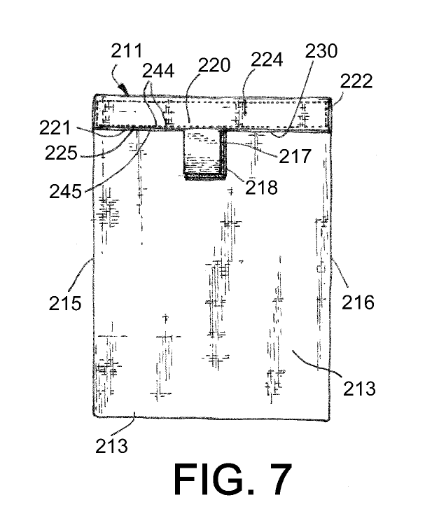

Referring to FIGS. 6-9, the first containment member 211 has a front or first panel 213 and back or second panel 214 which are joined together or folded at their edges 215, 216. According to a preferred embodiment, the first panel 213 and second panel 214 may be formed from a single panel sheet. A second or inner layer 250 is provided and is shown in the inside out view of FIG. 7 with a seam 251 at its lower portion 252 and a joining seam 252 being disposed between the side edges 253, 254. The seam 252 preferably is disposed at a location between the side edges 253, 254. The first or outer layer 220 is shown having a first or front panel 213 and a back or second panel 214. The lateral edges 215, 216 of the first containment member 211 preferably are joined together with suitable joining means, such as, for example, the joining means shown and described herein in connection with the other embodiments. Preferably, as illustrated in FIGS. 6-9, the joining means is shown comprising a thread 229, such as nylon, cotton, or other composition, of suitable strength to hold the seam together to withstand repeated placement and removal of objects within the first containment member 211, as well as folding and storage the device 211.

The second or inner layer 250 preferably is attached with suitable attachment means so that the second or inner layer 250 together with the first or outer layer forms the bag of the first containment member 211.

A closure is provided to cover the opening 240 of the bag 211 and regulate access to the contents of the bag 211 and cover the opening. According to a preferred embodiment, the first containment member has a closure 220 provided at the top of the first panel 213 and second panel 214 and includes a first closure portion 221 and a second closure portion 222. The closure portions 221, 222 preferably may be reinforced with a layer of material such as the cover layers 224, 225 which overlay the respective surfaces of the first closure panel 221 and second closure panel 222. In a preferred embodiment of the bag 211 illustrated in FIGS. 6-9, the inner layer 250 may be configured to form the closure portions 221, 222 along with the outer layer first panel 213 and second panel 214.

As shown in FIG. 7, the closure 220 is configured to include a fastening element 230, such as, for example, a hook and loop fastener arrangement as illustrated in the embodiments of FIGS. 1 and 5. Referring to FIG. 9, a surface of hooks 231 is provided on one of the closure panels, such as on the second closure portion 222, and a surface of loops 232, which are matingly associated to be retained by and released from the hooks 231, is provided on a panel forming the body, such as on the outer surface of the front panel 213. The surface of hooks 231 and surface of loops 232 preferably are secured together to the outer front panel 213 and inner panel 250, and the outer back panel 214 and inner panel 250, respectively.

Similar to the embodiment shown and described herein in connection with FIGS. 1-3, the hook and loop surfaces 231, 232, respectively, may be attached to secure the closure panels portions 221, 222 over the open end portion 240 of the bag 211. The closure 220 preferably is constructed from two closure portions, such as the panel portions 221, 222 respectively. According to a preferred embodiment, a content “fill line” may be provided, similar to the line illustrated in FIG. 3, as a folding axis where a folding of the closure panels 221, 222 forward or rearward direction is accomplished to close the containment member 211. The closure panel portions 221, 222 preferably are each provided to have a length to provide a substantially overlap of the folded end (as may be measured relative to the “fill line”) of the bag 211, when the bag 211 is folded in a closed configuration.

As shown in connection with FIGS. 1-3, according to a preferred embodiment, the closure panel portions 221, 222 and the respective closure cover layers 224, 225 may be formed by stitching, as shown by the stitching 244, 245 in FIG. 7. The stitching preferably may secure the inner layer 250 and front panel 213 and rear panel 214 together at the closure. Additional edge stitching or treatment, not shown, may be provided to finish the edges of the closure panel portions 221, 222, and the edges of the respective layers 250 and 213, and 250 and 214. The containment member 211 may have openers 217, 218 similar to those openers 117, 118, described above, at the closure panel portions 221, 222, respectively.

The fabric material from which the first containment member 11, 111, 211 is constructed preferably comprises a metallic containing shielding material, such as, for example, a shieldable fabric. The shielding capability of the fabric, preferably, provides sufficient shielding of electromagnetic radiation, including, electromagnetic radiation such as radio waves that are transmitted for cellular telephone communications. According to preferred embodiments, the bags or first containment members 11, 111, 211 may be constructed from a suitable shielding fabric material that has a shielding effectiveness of at least about 30 dB, and preferably at least 60 dB, from 30 MHz to 1 GHz. A suitable material from which the bags 11, 111, and 211 may be constructed is a silver nylon rip stop material, which is a conductive shielding material. A first containment member 11 is illustrated in FIGS. 1-3 having a folded over closure 20, where the closure panels 21, 22 are folded, and a first containment member 211 is shown in FIGS. 7-9 having a closure 220 with closure panels 221, 222. According to alternate embodiments, the closures 20, 220 may be provided having a suitable size to permit closure panels 21, 22 and 221, 222 to be folded over a first time and a second time, or to be folded over multiple times.

While the invention has been described with reference to specific embodiments, the description is illustrative and is not to be construed as limiting the scope of the invention. Devices according to the invention, such as, for example, the first containment member 11, 11 and 211, shown and described herein, for example, may be used without the second containment member 12, and the second containment member 12 carried along with the first containment member 11 (or 111, 211) for use as needed. The first containment member 11, 111, 211 may be constructed, as described herein, from a material which is smooth and may be used with clothing. Unlike metal storage safes, which routinely have sharp edges, the first containment member 11, 111, 211 provides a shieldable environment and may be carried within garments or clothing of an individual without being likely to puncture or otherwise tear the clothing. Various modifications and changes may occur to those skilled in the art without departing from the spirit and scope of the invention described herein and as defined by the appended claims.

What is claimed is:

1. A storage device for containing items in a shielding environment that facilitates shielding from electromagnetic radiation, the device comprising:
a containment member being constructed from a fabric having electromagnetic shielding capabilities, including the ability to shield RF radiation;
said fabric being configured to define an environment with at least one opening for access thereto and to cover said at least one opening;
a closure configured and arranged so that when said closure is in a latching position to releasably hold said fabric in a first position wherein said opening is covered by said fabric, and upon said closure being released, to provide a position which permits uncovering of said opening.

2. The storage device of claim 1, wherein said containment member fabric comprises a fabric panel.

3. The storage device of claim 2, wherein said fabric panel includes a first layer and a second layer, and wherein said first layer substantially overlaps said second layer.

4. The storage device of claim 3, wherein said fabric first layer includes a first panel having panel edges that are joined together at a first panel joining location to form a pocket.

5. The device of claim 4, wherein said fabric first layer includes a second panel having panel edges that are joined together at a second panel joining location to form a pocket.

6. The device of claim 5, wherein said first panel and said second panel are configured to form a pocket, wherein said first panel defines an outer layer and wherein said second panel defines an inner layer.

7. The device of claim 5, wherein said first joining location and said second joining location are provided at different locations on said device.

8. The device of claim 7, wherein said opening is provided at one end of said device, and where said joining locations are provided substantially perpendicular to said opening.

2. The device of claim 1, wherein the fabric forming said body portion and said closure panel is constructed from a composition that includes a metallic coated fiber.

3. The device of claim 2, wherein said metallic coated fiber comprises a polymer fabric containing a metallic coating.

4. The device of claim 3, wherein the metallic coating comprises a metal selected from the group consisting of nickel, copper and mixtures thereof.

5. The device of claim 1, wherein the fabric forming said body portion and said closure panel is constructed from a polyester taffeta covered fabric having a coating of nickel, copper or combinations thereof.

6. The device of claim 1, wherein said fabric has a shielding effectiveness of between about 89-91 dB in the range of 100 MHz-1 GHz.

7. The device of claim 5, wherein said fabric has a shielding effectiveness of at least about 30 dB in the range of 30 MHz-1 GHz.

8. The device of claim 1, wherein said metallic coated fiber is present in an amount relative to other components of the fabric to provide RF shielding of said first containment member space.

9. The device of claim 1, wherein said fabric is constructed from a composition that includes a metallic based fiber.

10. The device of claim 9, wherein said metallic based fiber comprises a multistranded fiber wherein at least one strand includes a metallic fiber.

11. The device of claim 10, wherein said metallic based fiber comprises a thin metal wire conjugated yarn.

12. The device of claim 11, wherein said thin metal wire conjugated yarn includes a thin wire intermingled with natural or synthetic fibers.

13. The device of claim 12, wherein said yarn has (i) a core of a thin metal wire having a core diameter less than or equal to about 0.50μ and a natural or synthetic fiber, and (ii) an additional natural or synthetic fiber disposed around said core.

14. The device of claim 9, wherein said metallic based fiber is present in an amount relative to other components of the fabric to provide RF shielding of said first containment member space.

15. The device of claim 1, wherein said fabric comprises a silver fiber.

16. The device of claim 1, wherein said fabric has a suitable shielding effectiveness to shield RF energy.

17. The device of claim 1, wherein said fabric has a suitable shielding effectiveness to shield RF energy associated with wireless and cellular communications.

18. The device of claim 9, wherein said fabric has a suitable shielding effectiveness to shield RF energy.

19. The device of claim 9, wherein said fabric has a suitable shielding effectiveness to shield RF energy associated with wireless and cellular communications.
